(19) United States
(12) Patent Application Publication
(10) Pub. No.: US 2007/0068659 A1
(43) Pub. Date: Mar. 29, 2007

(54) THERMAL MODULE

(75) Inventors: CHING-BAI HWANG, Tu-Cheng,Taipei Hsien (TW); JIN-GONG MENG, SHENZHEN (CN)

Correspondence Address: PCE INDUSTRY, INC.;ATT. CHENG-JU CHIANG JEFFREY T. KNAPP, 458 E. LAMBERT ROAD, FULLERTON, CA, 92835, US

(73) Assignee: FOXCONN TECHNOLOGY CO., LTD., Tu-Cheng (TW)

(21) Appl. No.: 11/308,914

(22) Filed: May 25, 2006

(30) Foreign Application Priority Data
Sep. 23, 2005 (CN) 200510037471.0

(51) Int. Cl. H05K 7/20

(52) U.S. Cl. 165/121; 165/80.3; 165/104.33; 361/700; 361/697

(57) ABSTRACT

A thermal module (10) for dissipating heat from a heat-generating electronic component includes a base plate (11), and at least a fin assembly (14) disposed on the base plate. The fin assembly includes a plurality of fins (140) stacked together along a predetermined direction. At least a part of the fins each has a main body (141) forming an acute angle with the stack direction thereof.

### FIELD OF THE INVENTION

The present invention relates generally to thermal modules, and more particularly to a thermal module for dissipating heat generated by electronic components.

### DESCRIPTION OF RELATED ART

A thermal module generally includes a base plate, a blower mounted to a top side of the base plate, a fin assembly mounted at an outlet of the blower, and a plurality of heat pipes mounted to a bottom side of the base plate and thermally connected to a heat-generating electronic component with the fin assembly.

Each of the heat pipes includes an evaporator section contacting the heat-generating electronic component, a condenser section remote from the heat-generating electronic component and thermally contacting with the fin assembly, and an adiabatic section interconnecting the evaporator section and the condenser section.

In operation of the thermal module, the evaporator sections of the heat pipes absorb heat from the heat-generating component, and then transfer the heat to the condenser sections of the heat pipes via the evaporation and condensation of the working medium filled in the heat pipes. Then, the heat is transferred to the base plate and from there to the fin assembly. Finally, the heat is taken away by airflow flowing through the fin assembly. Thus, heat dissipation of heat generated by the heat-generating component is accomplished.

During the operation of the thermal module, the heat is finally taken away by the airflow flowing through the fin assembly. So improving the air convection efficiency of the fin assembly is key to improve the heat dissipation efficiency of the thermal module.

Conventionally, one way to improve the air convection efficiency of the fin assembly is to increase heat exchanging areas between the fin assembly and the airflow passing through the fin assembly. A first way to satisfy such requirement is to increase density of fins (i.e. increase the number of fins in a certain space) in the fin assembly. A second way is to increase the size of the fins. Both ways improve the heat dissipation efficiency of the thermal module. However, the first way increases the air resistance of the fin assembly, and further increases the noise of the thermal module as the airflow flows through the fin assembly. The second way increases the height of the fin assembly, and further increases the size of the thermal module, which violates the requirement for compact electronic products. Accordingly, a thermal module with an improved fin assembly which can overcome the problems associated with the conventional fin assembly is needed.

### SUMMARY OF THE INVENTION

The present invention relates to a thermal module for dissipating heat from a heat-generating electronic component. According to a preferred embodiment of the present invention, the thermal module includes a base plate, and at least one fin assembly disposed on the base plate. The fin assembly includes a plurality of fins stacked together along a predetermined direction. At least one part of the fins has a main body forming an acute angle with the stack direction thereof.

### BRIEF DESCRIPTION OF DRAWINGS

Many aspects of the present thermal module can be better understood with reference to the following drawings. The components in the drawings are not necessarily drawn to scale, the emphasis instead being placed upon clearly illustrating the principles of the present thermal module. Moreover, in the drawings, like reference numerals designate corresponding parts throughout the several views.

FIG. 1 is an exploded, isometric view of a thermal module according to a preferred embodiment of the present thermal module;

FIG. 2 is an assembled view of the thermal module of FIG. 1;

FIG. 3 is a front view of a first fin assembly of the thermal module of FIG. 2;

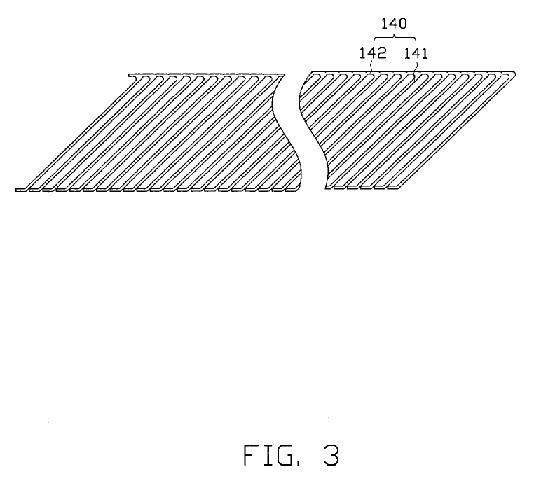

FIG. 4 is a front view of a first fin assembly of a thermal module according to a second embodiment of the present thermal module;

FIG. 5 is a front view of a first fin assembly of a thermal module according to a third embodiment of the present thermal module; and,

FIG. 6 is a front view of a first fin assembly of a thermal module according to a fourth embodiment of the present thermal module.

### DETAILED DESCRIPTION

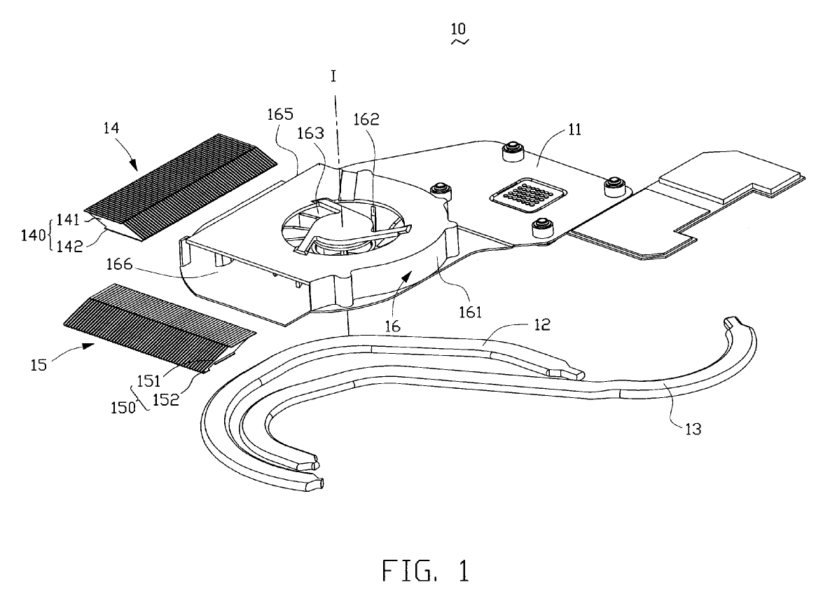

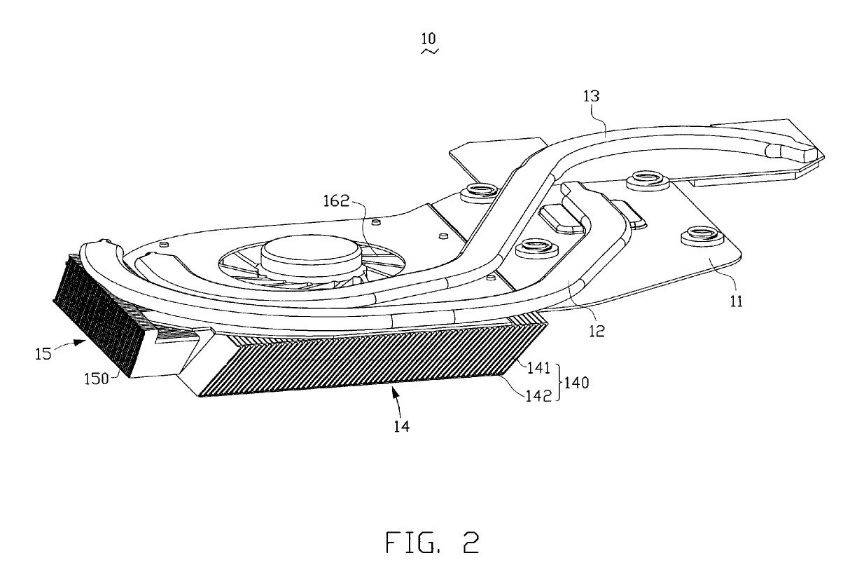

Referring to FIGS. 1 and 2, a thermal module 10 according to a preferred embodiment of the present thermal module is shown. The thermal module 10 includes a base plate 11, first and second heat pipes 12, 13 mounted to a bottom side of the base plate 11, first and second fin assemblies 14, 15 mounted to an upper side of the base plate 11, and a heat-dissipating fan 16 disposed adjacent to the first and second fin assemblies 14, 15.

The base plate 11 is made of materials having good heat conductive capability, for conducting heat from the first and second heat pipes 12, 13 to the first and second fin assemblies 14, 15. The first and second heat pipes 12, 13 are juxtaposed to each other, with opposite ends thereof respectively connecting with one of two heat-generating electronic components (not shown) and the bottom side of base plate 11, for transferring heat therebetween.

The heat-dissipating fan 16 is a centrifugal blower for providing an airflow with a high air pressure. The fan 16 includes a casing 161, a stator (not shown) mounted in the casing 161, and a rotor 162 rotatably disposed around the stator. The rotor 162 has a rotation axis I perpendicular to the base plate 11. A top wall (not labeled) of the casing 161 defines a through hole therein functioning as an air inlet 163 of the fan 16. A sidewall (not labeled) of the casing 161 defines two openings therein functioning as air outlets 165, 166 of the fan 16. As the fan 16 is activated, the rotor 162 rotates around the rotation axis I and drives the air in the casing 161 to leave the fan 16 for the first and second fin assemblies 14, 15 to take away heat therefrom.

The first and second fin assemblies 14, 15 are respectively mounted to the air outlets 165, 166 of the fan 16. The first and second fin assemblies 14, 15 respectively include a plurality of fins 140, 150. Each of the fins 140, 150 parallels to and has a same configuration with a corresponding fin 140, 150. The fins 140, 150 each has a flattened main body 141, 151, and two parallel flanges 142, 152 extending forwardly from two opposite ends of the main body 141, 151.

Arrangements of the fins 140, 150 of the first and second fin assemblies 14, 15 will be disclosed hereinafter. In this embodiment, the fins 140 of the first fin assembly 14 have the same arrangement as the fins 150 of the second fin assembly 15. The arrangement of the fins 140 of the first fin assembly 14 is thus disclosed, standing for the arrangement of the fins 150 of the second fin assembly 15.

The fins 140 of the first fin assembly 14 are stacked together along a straight line, with the flanges 142 of a rear fin 140 abutting against the main body 141 of a front fin 140. Alternatively, the fins 140 of the first fin assembly 14 may be stacked together along a curve, which disposes the ends of the fins 140 adjacent to the rotor 162 of the fan 16 along the curve. A plurality of air passages are formed between adjacent fins 140 to allow airflow to flow therethrough. A contacting surface is formed at the bottommost of the first fin assembly 14, for contacting with an upper surface of the base plate 11. An acute angle is formed between one flange 142 of each fin 140 and the main body 141 thereof. So the main body 141 of each fin 140 forms a same acute angle with the stack direction of the fins 140 of the first fin assembly 14. Another acute angle complemented with that acute angle is also formed between the main body 141 of each fin 140 and the rotation axis I of the rotor 162 of the fan 16.

Hereinafter, three examples will be disclosed to explain the benefits of the thermal module 10 of the present invention, as compared to the conventional thermal module with the main bodies of fins perpendicular to the stack direction of the fins; the height of the fins 140 of the first fin assembly 14 of the present thermal module 10 are equal to that of the fins of the fin assembly of the conventional thermal module.

According to the law of sine, when the acute angle is 30°, the length and accordingly the heat dissipating area of the main bodies 141 the fins 140 are two times to those of the main bodies of the conventional fins, respectively, when the fins 140 and the conventional fins have the same height. The heat dissipating areas of the main bodies 141 of the fins 140 of the first fin assembly 14 are one time larger than that of the main bodies of the fins of the conventional thermal module. When the acute angle is 45°, the heat dissipating area of the main bodies 141 of the fins 140 is substantially 1.4 times that of the main bodies of the fins of the conventional thermal module. When the acute angle is 60°, the heat dissipating area of the main bodies 141 of the fins 140 is substantially 1.2 times that of the main bodies of the fins of the conventional thermal module. Therefore, the thermal module of the present invention has a better heat dissipation efficiency than the conventional thermal module, without the necessity to increase the height and density of the fin assembly.

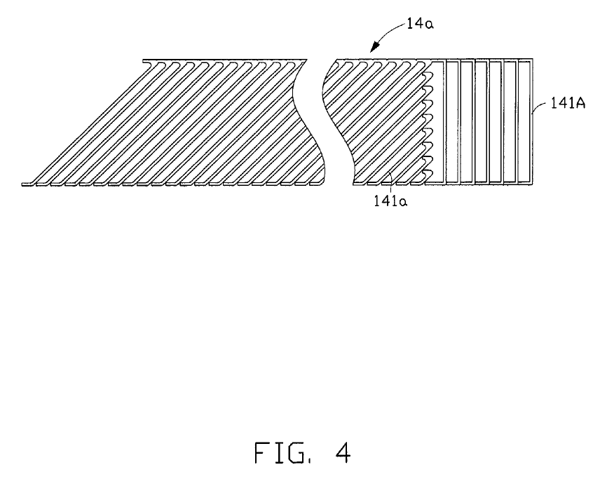

Referring to FIG. 4, the first fin assembly 14a of the present invention may be divided into two parts. The main bodies 141A of the fins of one part of the first fin assembly 14a extend at a right angle to the stack direction, whilst the main bodies 141a of the fins of the other part are inclined relative to the stack direction with an acute angle. Alternatively, the first fin assembly may be divided into more than two parts, with acute angles formed between the parts of the first fin assembly and stack direction being different from each other.

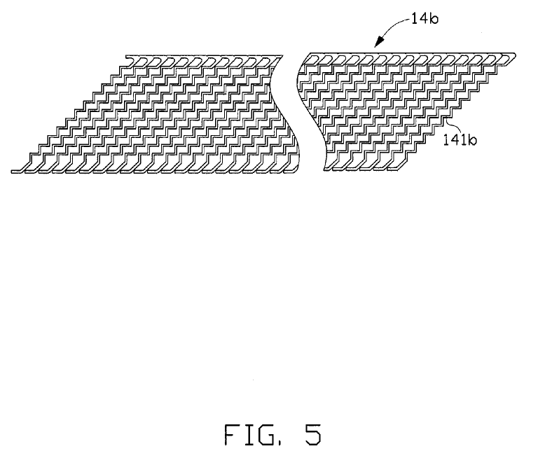

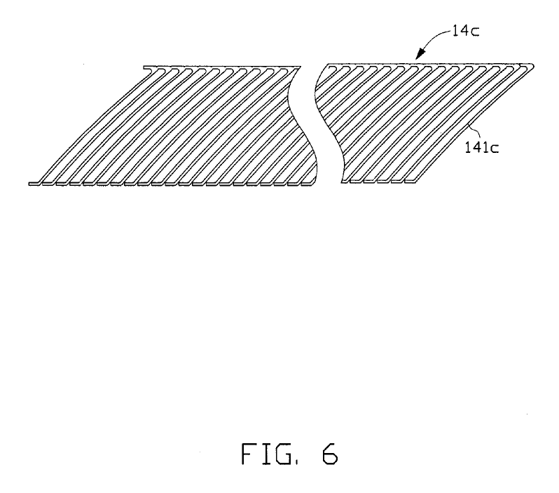

Referring to FIGS. 5 and 6, the third and fourth embodiments of the first fin assembly of the thermal module of the present invention are shown. In the third embodiment, the main bodies 141b of all the fins of the first fin assembly 14b have zigzag-shaped configurations, as viewed from front or rear sides thereof. In the fourth embodiment, the main bodies 141c of all the fins of the first fin assembly 14c have slightly curve-shaped configurations as viewed from the same sides. Alternatively, the main bodies 141 of the fins 140 of the first fin assembly 14 may have different configurations.

In the hereinbefore mentioned embodiments, the fins 150 of the second fin assembly 15 have a similar arrangement with the fins of the first fin assembly 14/14a/14b/14c as set forth above. Alternatively, the fins 150 of the second fin assembly 15 may have a different arrangement with the fins 140 of the first fin assembly 14.

In the present invention, the dissipating area of the fins 140, 150 is larger than the dissipating area of the fins of the conventional thermal module. This increases the heat dissipating area of the first and second fin assemblies of the thermal module, without increasing the height of the thermal module. So the present thermal module is capable of dissipating more heat than the conventional thermal module. The heat dissipation efficiency of the present thermal module is thus increased.

It is to be understood, however, that even though numerous characteristics and advantages of the present invention have been set forth in the foregoing description, together with details of the structure and function of the invention, the disclosure is illustrative only, and changes may be made in detail, especially in matters of shape, size, and arrangement of parts within the principles of the invention to the full extent indicated by the broad general meaning of the terms in which the appended claims are expressed.

What is claimed is:

1. A thermal module adapted for dissipating heat from a heat-generating electronic component comprising:
a base plate; and
at least a fin assembly disposed on the base plate, the fin assembly comprising a plurality of fins stacked together along a predetermined direction, at least a part of the fins each having a main body forming an acute angle to the stack direction thereof.

2. The thermal module as described in claim 1, wherein the acute angle is chosen from the group consisting of 30°, 45°, and 60°.

3. The thermal module as described in claim 1, wherein the fins of the fin assembly are stacked along a straight line or a curve line.

4. The thermal module as described in claim 1, further comprising a centrifugal blower mounted on the base plate, the centrifugal blower having at least an air outlet where the fin assembly is mounted thereat.

5. The thermal module as described in claim 4, wherein the blower has two air outlets, the at least a fin assembly comprises first and second fin assemblies respectively mounted to the air outlets.

6. The thermal module as described in claim 5, wherein the first and second fin assemblies each comprising a plurality of parallel fins, the angles formed between the main bodies of the fins and the stack direction of the first fin assembly are different from that formed between the main bodies of the fins and the stack direction of the second fin assembly.

7. The thermal module as described in claim 1, wherein the angle formed between the main body of the at least a part of the fins of the at least a fin assembly and that stack direction are different from angles formed between the main bodies of other parts of the fins of the at least a fin assembly and that stack direction.

8. The thermal module as described in claim 7, wherein the main body of at least a fin of the other parts of the at least a fin assembly is perpendicular to that stack direction.

9. The thermal module as described in claim 1, wherein the main body of each fin of the at least a fin assembly is chosen from the group consisting of linear-shaped, zigzag-shaped and curve-shaped in shape.

10. A thermal module comprising:
a blower comprising at least an air outlet and a rotor having a rotation axis; and at least a fin assembly disposed at the air outlet of the blower, the at least a fin assembly comprising a plurality of fins each having a main body, the main body of at least a fin forming an acute angle with the rotation axis of the blower.

11. The thermal module as described in claim 10, further comprising a base plate and at least a heat pipe, wherein the blower and the at least a fin assembly are mounted to one side of the base plate, the heat pipe is mounted to an opposite side of the base plate.

12. The thermal module as described in claim 10, wherein the fins of the at least a fin assembly are stacked along a straight line or a curve line.

13. The thermal module as described in claim 10, wherein the acute angle is chosen from the group consisting of 30°, 45°, and 60°.

14. The thermal module as described in claim 10, wherein the main bodies of the fins of at least a part of the at least a fin assembly are parallel to the rotation axis of the blower.

15. A thermal module comprising:
a base plate with a top surface mounted with a fan and a bottom surface mounted with a heat pipe, the heat pipe having an evaporation end adapted for contacting with a heat-generating electronic component and a condensation end;
a fin assembly thermally connecting with the condensation end of the heat pipe and through which an airflow generated by the fan flows, wherein the fin assembly consists of a plurality of fins horizontally stacked together along a direction, each of the fins having a main body inclined relative to the stacked direction of the fins with an acute angle.

16. The thermal module of claim 15, wherein the main body is formed as having a zigzag shape.

17. The thermal module of claim 15, wherein the main body is formed as having an arced shape.

18. The thermal module of claim 15, wherein the main body is formed as having a straight shape.

19. The thermal module of claim 15, wherein the acute angle is ranged from 30°to 60°.
